(19) United States
(12) Patent Application Publication
(10) Pub. No.: US 2023/0096055 A1
(43) Pub. Date: Mar. 30, 2023

(54) ORGANIC LIGHT EMITTING DIODE DISPLAY PANEL AND MANUFACTURING METHOD THEREOF

(71) Applicant: Wuhan China Star Optoelectronics Semiconductor Display Technology Co., Ltd., Wuhan, Hubei (CN)

(72) Inventor: Xiao DU, Wuhan, Hubei (CN)

(73) Assignee: Wuhan China Star Optoelectronics Semiconductor Display Technology Co., Ltd., Wuhan, Hubei (CN)

(21) Appl. No.: 16/979,190

(22) PCT Filed: Jun. 22, 2020
(86) PCT No.: PCT/CN2020/097529

§ 371 Date: Sep. 9, 2020

(30) Foreign Application Priority Data
May 7, 2020 (CN) 202010384404.0

(51) Int. Cl. H10K 59/122; H10K 71/00

(52) U.S. Cl. CPC H01L 27/3246; H01L 51/56; H01L 27/3276

(57) ABSTRACT

The present disclosure provides an organic light emitting diode (OLED) display panel and a manufacturing method thereof. The OLED display panel includes a substrate having a display area and a plurality of pixel units arranged in an array in the display area. Each of the pixel units includes a pixel opening area, and the pixel opening area can be adjusted according to a luminance of the corresponding pixel unit, so as to ensure uniform display of the OLED display panel.

### FIELD OF INVENTION

The present disclosure relates to the field of display technologies, and particularly relates to an organic light emitting diode (OLED) display panel and a manufacturing method of the OLED display panel.

### BACKGROUND OF INVENTION

In design of conventional organic light emitting diode (OLED) display panels, because a display signal and a driving current are input through a bonding area of the display panel, and there is a problem of IR drop in the display panel from an area adjacent to the bonding area to an area away from the bonding area, luminance of pixel units adjacent to the bonding area is greater than luminance of pixel units away from the bonding area. Therefore, when designing an OLED display panel, it is necessary to simulate and compensate its peripheral circuit.

However, as foldable OLED display panels are gradually used in terminal products, specifications of the OLED display panel tend to gradually increase. In OLED display panels with larger specifications, that merely designing a compensation circuit to perform display compensation cannot optimize display uniformity of the display panel.

### TECHNICAL PROBLEMS

As foldable OLED display panels are gradually used in terminal products, specifications of the OLED display panel tend to gradually increase. In OLED display panels with larger specifications, that merely designing a compensation circuit to perform display compensation cannot optimize display uniformity of the display panel, and a design including a large number of compensation circuits also limits further narrowing of a panel frame.

### TECHNICAL SOLUTIONS

Embodiments of the present disclosure provide an organic light emitting diode (OLED) display panel and a manufacturing method of the OLED display panel to solve a technical problem of uniform display of OLED display panels in prior art.

The present disclosure provides an OLED display panel, including:

a substrate comprising a display area; and

a plurality of pixel units arranged in an array in the display area; and

wherein each of the pixel units comprises a pixel opening area, and the pixel opening area is capable to be adjusted according to a luminance of a corresponding one of the pixel units, so as to ensure uniform display of the OLED display panel.

In the OLED display panel provided in the present disclosure, the OLED display panel further comprises a bonding area disposed outside the display area;

wherein the display area comprises a plurality of pixel areas arranged in a column, and each of the pixel areas comprises at least one row of the pixel units; and

wherein the pixel opening area of each of the pixel units in the pixel areas adjacent to the bonding area is less than the pixel opening area of each of the pixel units in the pixel areas away from the bonding area.

In the OLED display panel provided in the present disclosure, the pixel opening area of each of the pixel units in a same one of the pixel areas is same.

In the OLED display panel provided in the present disclosure, a plurality of fan-shaped wirings are disposed in the bonding area, and each of the fan-shaped wirings is connected to a corresponding one of the pixel units; and

wherein the plurality of fan-shaped wirings comprise first fan-shaped wirings and second fan-shaped wirings, a length of each of the first fan-shaped wirings is less than a length of each of the second fan-shaped wirings, and the pixel opening area of each of the pixel units connected to the first fan-shaped wirings is less than the pixel opening area of each of the pixel units connected to the second fan-shaped wirings.

In the OLED display panel provided in the present disclosure, the plurality of pixel units comprise at least one first pixel unit, the at least one first pixel unit is disposed in the display area irregularly, and a luminance of the first pixel unit is less than a preset luminance; and

wherein the pixel opening area of the first pixel unit is greater than a preset pixel opening area.

In the OLED display panel provided in the present disclosure, the plurality of pixel units comprise at least one second pixel unit, the at least one second pixel unit is disposed in the display area irregularly, and a luminance of the second pixel unit is greater than a preset luminance; and

wherein the pixel opening area of the second pixel unit is less than a preset pixel opening area.

The present disclosure further provides an OLED display panel, including:

a substrate comprising a display area; and

a plurality of pixel units arranged in an array in the display area; and

wherein each of the pixel units comprises a pixel opening area, and the pixel opening area is capable to be adjusted according to a luminance of a corresponding one of the pixel units, so as to ensure uniform display of the OLED display panel;

wherein the OLED display panel further comprises a bonding area disposed outside the display area;

wherein the display area comprises a plurality of pixel areas arranged in a column, and each of the pixel areas comprises at least one row of the pixel units;

wherein the pixel opening area of each of the pixel units in the pixel areas adjacent to the bonding area is less than the pixel opening area of each of the pixel units in the pixel areas away from the bonding area;

wherein each of the pixel units comprises a thin film transistor, an anode, and a pixel definition layer successively disposed on the substrate; and

wherein in any one of the pixel units, the pixel definition layer comprises an opening, and the pixel opening area of a corresponding one of the pixel units is capable to be adjusted according to a specification of the opening.

In the OLED display panel provided in the present disclosure, the pixel opening area of each of the pixel units in a same one of the pixel areas is same.

In the OLED display panel provided in the present disclosure, a plurality of fan-shaped wirings are disposed in the bonding area, and each of the fan-shaped wirings is connected to a corresponding one of the pixel units; and

wherein the plurality of fan-shaped wirings comprise first fan-shaped wirings and second fan-shaped wirings, a length of each of the first fan-shaped wirings is less than a length of each of the second fan-shaped wirings, and the pixel opening area of each of the pixel units connected to the first fan-shaped wirings is less than the pixel opening area of each of the pixel units connected to the second fan-shaped wirings.

In the OLED display panel provided in the present disclosure, the plurality of pixel units comprise at least one first pixel unit, the at least one first pixel unit is disposed in the display area irregularly, and a luminance of the first pixel unit is less than a preset luminance; and

wherein the pixel opening area of the first pixel unit is greater than a preset pixel opening area.

In the OLED display panel provided in the present disclosure, the plurality of pixel units comprise at least one second pixel unit, the at least one second pixel unit is disposed in the display area irregularly, and a luminance of the second pixel unit is greater than a preset luminance; and

wherein the pixel opening area of the second pixel unit is less than a preset pixel opening area.

Accordingly, the present disclosure further provides a manufacturing method of an OLED display panel, including:

providing a substrate, wherein the substrate comprises a display area; and

forming a plurality of pixel units in the display area, each of the pixel units comprising a pixel opening area, and adjusting the pixel opening area according to a luminance of a corresponding one of the pixel units, so as to ensure uniform display of the OLED display panel.

In the manufacturing method of the OLED display panel provided in the present disclosure, a current distribution of the OLED display panel is simulated by simulation software, and the luminance of each of the pixel units is obtained according to the current distribution.

In the manufacturing method of the OLED display panel provided in the present disclosure, the OLED display panel is illumined, and a luminance distribution of the OLED display panel is collected by an image acquisition device, so as to obtain the luminance of each of the pixel units.

### BENEFICIAL EFFECTS

The present disclosure provides an OLED display panel and a manufacturing method of the OLED display panel, the OLED display panel includes a substrate, the substrate has a display area, a plurality of pixel units are arranged in an array in the display area, and an pixel opening area of the pixel unit can be adjusted according to a luminance of the corresponding pixel unit, so the luminance of each of the pixel units is same, thereby optimizing display uniformity of the OLED display panel.

### DESCRIPTION OF DRAWINGS

In order to more clearly explain technical solutions in embodiments of the present disclosure, following will briefly introduce the drawings required in description of the embodiments. Obviously, the drawings in the following description are merely some embodiments of the present disclosure. For those skilled in the art, without any creative work, other drawings can be obtained based on these drawings.

FIG. 1 is a first planar and schematic view of an organic light emitting diode (OLED) display panel provided by the present disclosure.

FIG. 2 is a second planar and schematic view of the OLED display panel provided by the present disclosure.

FIG. 3 is a first planar and schematic view of adjacent pixel areas in FIG. 2 provided by the present disclosure.

FIG. 4 is a second planar and schematic view of the adjacent pixel areas in FIG. 2 provided by the present disclosure.

FIG. 5 is a second planar and schematic view of the adjacent pixel areas in FIG. 2 provided by the present disclosure.

FIG. 6 is a third planar and schematic view of the OLED display panel provided by the present disclosure.

FIG. 7 is a fourth planar and schematic view of the OLED display panel provided by the present disclosure.

FIG. 8 is a sectional and schematic view along a line XX′ in FIG. 1 provided by the present disclosure.

FIG. 9 is another sectional and schematic view along the line XX′ in FIG. 1 provided by the present disclosure.

FIG. 10 is a flowchart shows a manufacturing method of an OLED display panel provided by the present disclosure.

### DETAILED DESCRIPTION OF EMBODIMENTS

The technical solutions in the embodiments of the present disclosure will be clearly and completely described with reference to the accompanying drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative work fall into protection scope of the present disclosure.

In the description of the present disclosure, it should be understood that orientational or positional relationships indicated by terms, such as “thickness”, “on”, “under”, “perpendicular”, “side”, etc., are based on the orientational or positional relationships shown in the drawings, and are merely for convenience of describing the present disclosure and simplifying the description, and does not indicate or imply that the device or element referred to must have a specific orientation, be constructed and operate in a specific orientation, and therefore cannot be understood as a limitation on the present disclosure. Terms “first” and “second” are used herein for purposes of description, and should not be interpreted as indication or implication of relative importance or implicitly indicating a number of technical features indicated. Thus, the features defined as “first” and “second” may explicitly or implicitly include one or more of the features, and therefore cannot be understood as a limitation on the present disclosure.

It should be noted that in the description of all embodiments of the present disclosure, multiple pixel units in the OLED display panel may be arranged according to various pixel structures, such as a traditional RGB arrangement, that is, each of the pixel units is composed of red, green, and blue subpixel units; the pixel structure may also be a new arrangement that subpixel units are shared between the pixel units, such as a Delta-type of or a PENTILE-type. That is, center points of a plurality of pixel units in the embodiments of the present disclosure are arranged according to a pixel arrangement rule in the prior art, the difference is that pixel opening areas of the pixel units located in different areas of the OLED display panel are different. Among them, the above-mentioned multiple pixel arrangement types are technologies understood by those skilled in the art and will not be repeated herein. Following embodiments of the present disclosure are described with the plurality of pixel units arranged according to a conventional RGB pixel structure, but it cannot be understood as a limitation to the present disclosure.

In addition, in the description of all embodiments of the disclosure, the OLED display panel may adopt a bilateral bonding or may be driven by a dual driver chip, which is not limited in the disclosure. Each of the following embodiments takes an example that the OLED display panel adopts a unilateral bonding and is driven by a driver chip for description, but it cannot be understood as a limitation to the present disclosure.

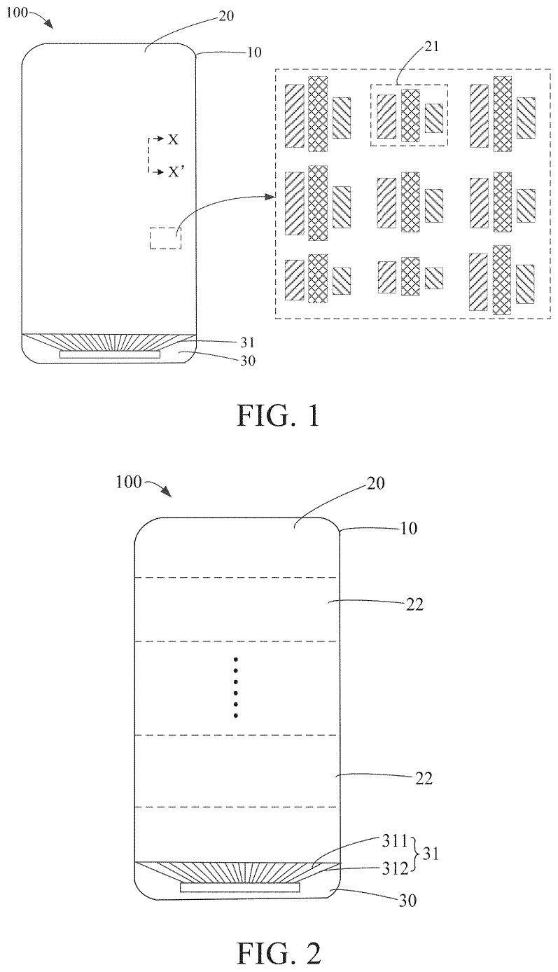

Referring to FIG. 1, the present disclosure provides an organic light emitting diode (OLED) display panel 100. The OLED display panel 100 includes a substrate 10 and a plurality of pixel units 21. The substrate 10 has a display area 20, and the plurality of pixel units 21 are arranged in an array in the display area 20. Wherein, each of the pixel units 21 includes a pixel opening area, and the pixel opening area can be adjusted according to a luminance of the corresponding pixel unit 21, so as to ensure uniform display of the OLED display panel 100.

Specifically, the luminance of each pixel unit 21 may be obtained according to a current distribution of the OLED display panel 100, and the current distribution is simulated by simulation software. The luminance of each pixel unit 21 may also be obtained according to luminance distributions of manufactured samples of the OLED display panel 100, and the luminance distribution is collected by an image acquisition device. The luminance of each pixel unit 21 may also be obtained by other methods that can test the current distribution or luminance parameters of the OLED display panel 100, which is not specifically limited in the disclosure.

Furthermore, according to the luminance corresponding to each pixel unit 21, the pixel opening area of the pixel unit 21 can be adjusted separately, or the pixel opening areas of the pixel units 21 can be adjusted according to corresponding located regions and certain rules, which is not specifically limited in the disclosure.

The present disclosure provides the OLED display panel 100, the OLED display panel 100 includes the substrate 10, the substrate 10 has the display area 20, the plurality of pixel units 21 are arranged in an array in the display area 20, and the pixel opening area of each pixel unit 21 is adjusted according to the luminance of the corresponding pixel unit 21, so the luminance of each pixel unit 21 is the same, thereby optimizing display uniformity of the OLED display panel 100.

Referring to FIG. 2, in an embodiment of the present disclosure, the OLED display panel 100 further includes a bonding area 30 disposed outside the display area 20. The display area 20 includes a plurality of pixel areas 22 arranged in a column, and each of the pixel areas 22 includes at least one row of the pixel units 21 (not labeled in the figure). Wherein, the pixel opening areas of the pixel units 21 in the pixel areas 22 adjacent to the bonding area 30 are less than the pixel opening areas of the pixel units 21 in the pixel areas 22 away from the bonding area 30.

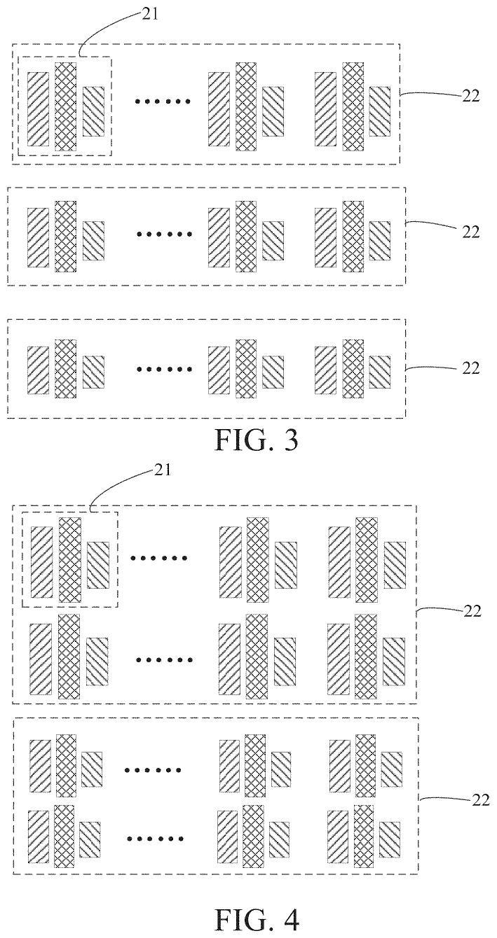

Specifically, in some embodiments, referring to FIG. 3, each pixel area 22 includes one row of the pixel units 21. The pixel opening area of the pixel unit 21 in adjacent pixel areas 22 gradually increases along a direction from the bonding area 30 to the display area 20. The pixel opening areas of the pixel units 21 in a same pixel area 22 can be adjusted separately according to corresponding luminance.

In some embodiments, each pixel area 22 includes at least two rows of the pixel units 21. Referring to FIG. 4, an embodiment of the present disclosure takes that each pixel area 22 includes two rows of the pixel units 21 as an example for description, but it cannot be understood as a limitation to the embodiments of the present disclosure. Wherein, the pixel opening area of the pixel unit 21 in adjacent pixel areas 22 gradually increases along a direction from the bonding area 30 to the display area 20. The pixel opening areas of the pixel units 21 in a same pixel area 22 can be adjusted separately according to corresponding luminance.

Furthermore, in some embodiment, the pixel opening area of each pixel unit 21 in a same pixel area 22 is same. Referring to FIG. 3 and FIG. 4, on a premise of ensuring same luminance of multiple pixel areas 22, the pixel units 21 located in a same pixel area 22 may have the same pixel opening area, thereby simplifying production process and saving costs. Additionally, considering limitation of an actual manufacturing process, a luminance difference threshold may be set, and along a direction from the bonding area 30 to the display area 20, if a luminance difference of the adjacent pixel areas 22 is less than the luminance difference threshold, the luminance of the adjacent pixel areas 22 can be regarded as consistent, thereby further simplifying the production process.

It can be understood that, a luminance of the pixel unit 21 adjacent to the bonding area 30 is greater than a luminance of the pixel unit 21 away from the bonding area 30, and the corresponding pixel opening area is smaller. In the manufacturing process, the pixel unit 21 with a smaller pixel opening area has a higher requirement for manufacturing process. Therefore, the plurality of pixel areas 22 may include a same number of rows of the pixel units 21, or may include various number of rows of the pixel units 21, which is not limited in the disclosure. For example, the pixel area 22 adjacent to the bonding area 30 may include fewer rows of the pixel units 21 to reduce an amount of pixel units 21 with a smaller pixel opening area, thereby reducing requirement for the manufacturing process and optimizing display uniformity of the OLED display panel 100.

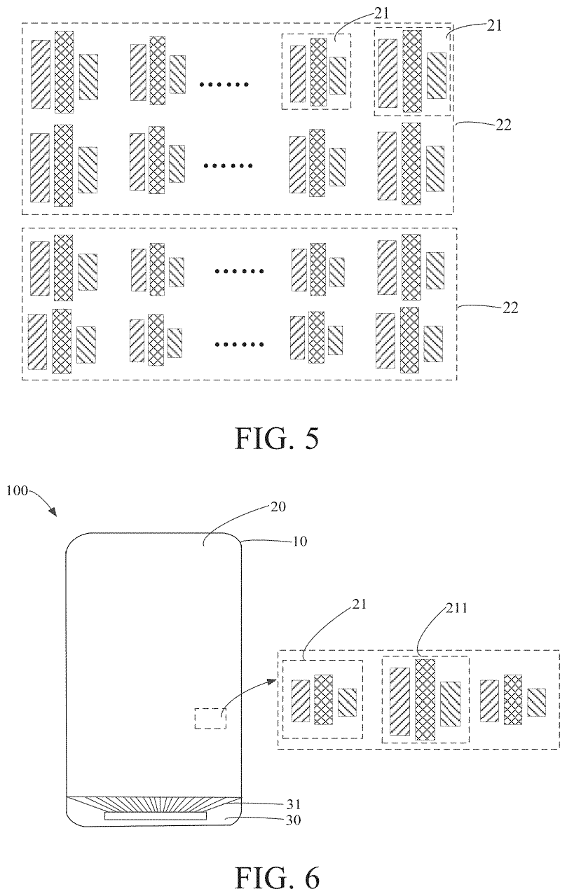

Furthermore, referring to FIG. 2 and FIG. 5, in some embodiments, a plurality of fan-shaped wirings 31 are disposed in the bonding area 30. Each of the fan-shaped wirings 31 is correspondingly connected to one of the pixel units 21. Wherein, the plurality of fan-shaped wirings 31 include first fan-shaped wirings 311 and second fan-shaped wirings 312. A length of the first fan-shaped wiring 311 is less than a length of the second fan-shaped wiring 312, and the pixel opening areas of the pixel units 21 connected to the first fan-shaped wirings 311 are less than the pixel opening areas of the pixel units 21 connected to the second fan-shaped wirings 312.

It can be understood that display signals and currents of the OLED display panel 100 are input from the bonding area 30 to the pixel units 21 through the corresponding fan-shaped wirings 31. Because the plurality of fan-shaped wirings 31 have various lengths, current losses caused by IR drop vary, wherein along the direction from the bonding area 30 to the display area 20 and in a same row of the pixel units 21, a luminance of the pixel units 21 connected to the first fan-shaped wirings 311 are greater than a luminance of the pixel units 21 connected to the second fan-shaped wirings 312. Thus, while the luminance difference of the adjacent pixel areas 22 is less than the luminance difference threshold, in a same row of the pixel units 21, the pixel opening areas of the pixel units 21 are designed, so that in the same row, the pixel opening area of each of the pixel units 21 connected to the first fan-shaped wirings 311 is less than the pixel opening area of each of the pixel units 21 connected to the second fan-shaped wirings 312, thereby optimizing display uniformity of a same pixel area 22 and further optimizing display uniformity of the OLED display panel 100.

It should be noted that the first fan-shaped wirings 311 and the second fan-shaped wirings 312 are merely for better description of the embodiment of the present disclosure, and cannot be understood as indicating or implying relative importance or implicitly indicating a number of the fan-shape wirings 31 in the embodiments of the present disclosure.

In some embodiments, referring to FIG. 6, the plurality of pixel units 21 include at least one first pixel unit 211. The at least one first pixel unit 211 is disposed in the display area 20 irregularly, and a luminance of the first pixel unit 211 is less than a preset luminance; wherein the pixel opening area of the first pixel unit 211 is greater than a preset pixel opening area.

It can be understood that although distances between the plurality of pixel units 21 and the bonding area 30 vary, and the lengths of the plurality of fan-shaped wirings 31 are different, the distance between each pixel unit 21 and the bonding area 30 and the length of the fan-shaped wiring 31 have certain rules. Therefore, the pixel opening areas of the pixel units 21 located at different areas of the OLED display panel 100 can be set according to a certain rule. For example, referring to FIG. 2, along the direction from the bonding area 30 to the display area 20, the luminance difference between the adjacent pixel areas 22 is less than a luminance difference threshold, and the pixel opening areas of the pixel units 21 located in a same pixel area 22 are same, that is, the pixel units 21 located in different areas of the OLED display panel 100 have a preset luminance and the preset pixel opening area. However, in a manufacturing process of the OLED display panel 100, due to imperfections of the manufacturing process or influence of external environment, the luminance of the at least one first pixel unit 211 in the OLED display panel 100 is always less than the preset luminance, thereby causing abnormal display of the OLED display panel 100. Thus, the pixel opening area of the first pixel unit 211 can be set to be greater than the preset pixel opening area, thereby allowing the luminance of the first pixel unit 211 to reach the preset luminance, optimizing display uniformity in the same pixel area 22, and further optimizing display uniformity of the OLED display panel 100.

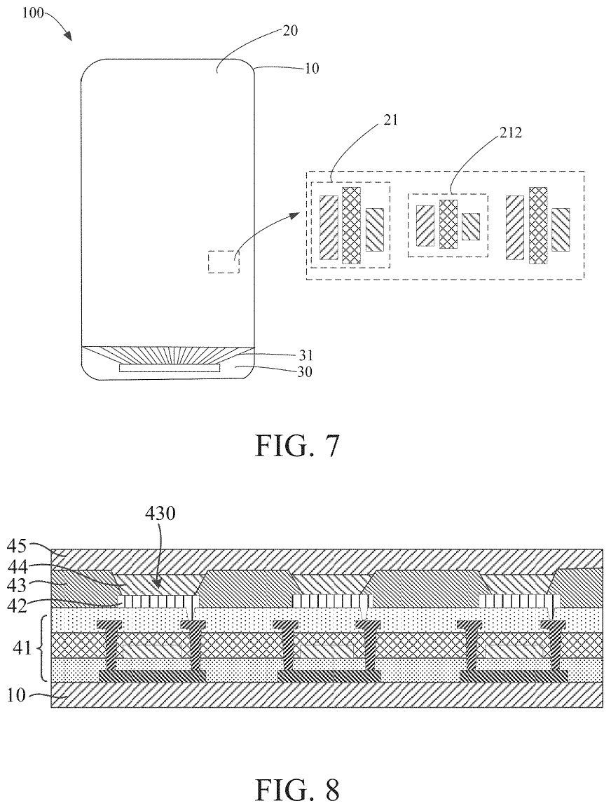

In some embodiments, referring to FIG. 7, the plurality of pixel units 21 include at least one second pixel unit 212. The at least one second pixel unit 212 is disposed in the display area 20 irregularly, and a luminance of the second pixel unit 212 is less than a preset luminance. Wherein the pixel opening area of the second pixel unit 212 is greater than the preset pixel opening area.

As described above, in the process of the OLED display panel 100, due to imperfection of the process or influence of external environment, the at least one second pixel unit 212 in the OLED display panel 100 has a luminance always greater than the preset luminance, thereby causing abnormal display of the OLED display panel 100. Thus, the pixel opening area of the second pixel unit 212 can be set to be less than the preset pixel opening area, thereby optimizing the display uniformity in a same pixel area 22, and further optimizing the display uniformity of the OLED display panel 100.

It should be noted that the first pixel unit 211 and the second pixel unit 212 may be presented individually or simultaneously. The first pixel unit 211 and the second pixel unit 212 specifically can be set according to the luminance corresponding to each pixel unit 21 in the OLED display panel 100, which is not limited in the present disclosure. Additionally, terms such as “first pixel unit 211” and “second pixel unit 212” are used merely to better describe the embodiments of the present disclosure, and cannot be interpreted as indicating or implying relative importance or implicitly indicating a number of pixel units 21 in the embodiments of the present disclosure.

Additionally, referring to FIG. 8, each of the pixel units 21 includes a thin film transistor 41, an anode 42, and a pixel definition layer 43 successively disposed on the substrate 10. In any one of the pixel units 21, the pixel definition layer 43 includes an opening 430. A luminescent material layer 44 is deposited in the opening 430. The luminescent material layer 44 is provided with a cathode 45 thereon. The luminescent material layer 44 is in contact with the anode 42 and the cathode 45, respectively.

In the embodiment of the present disclosure, the pixel opening area of the pixel unit 21 can be adjusted according to a specification of the opening 430. The embodiment of the present disclosure takes that the pixel opening areas of the pixel units 21 gradually increase along a direction away from the bonding area 30 as an example, it can be known that as the pixel opening areas of the pixel units 21 increase, corresponding specifications of the openings 430 also gradually increase. It can be understood that as the specification of the opening 430 increases, an area of the luminescent material layer 44 deposited in the opening 430 also increases, and when a same current flows through the luminescent material layer 44, a luminance of light emitted from the luminescent material layer 44 is greater.

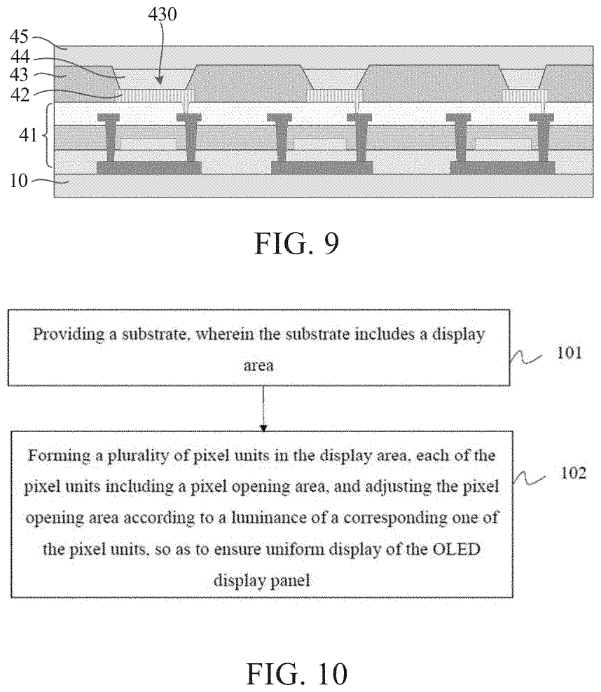

In some embodiments, due to influence of production process and the like, luminance various greatly in the plurality of pixel units 21, and the pixel opening areas need to be greatly adjusted, and accordingly, each of the openings 43 needs to be greatly adjusted. In an actual process, there is a certain reserved space between the opening 430 and a boundary of the anode 42, if an adjustment of the opening 430 is extensive, the boundary of the anode 42 should be reduced or enlarged at the same time, referring to FIG. 9. This solution can maintain connection consistency between the luminescent material layer 44 and the anode 42 in each pixel unit 21, and at the same time, the anode 42 decreases as the specification of the opening 430 decreases, which can improve a light transmission rate and the luminescent of the OLED display panel.

Referring to FIG. 10 and FIG. 1, the present disclosure further provides a manufacturing method of an OLED display panel, specifically including steps as follows:

101, providing a substrate, wherein the substrate includes a display area.

Specifically, the substrate 10 may be a glass substrate, a resin substrate, a polyimide film (PI) flexible substrate, or other types of substrates not elaborated herein.

102, forming a plurality of pixel units in the display area, each of the pixel units including a pixel opening area, and adjusting the pixel opening area according to a luminance of a corresponding one of the pixel units, so as to ensure uniform display of the OLED display panel.

In some embodiments, a current distribution of the OLED display panel 100 can be simulated by simulation software, and the luminance of the pixel unit 21 is obtained according to the current distribution.

Specifically, the simulation software is used to simulate line resistances between various areas of the OLED display panel 100 and signal input terminals and is used to simulate a current reduction caused by the resistances, in this way, the current distribution of the OLED display panel 100 is simulated, and then the current distribution is used to calculate the luminance of each pixel unit 21, the method is simple and easy to operate.

In some embodiments, the OLED display panel 100 is illuminated, and a luminance distribution of the OLED display panel 100 is collected by an image acquisition device, so as to obtain the luminance of each of the pixel units 21.

Specifically, some pre-made samples of the OLED display panel 100 are tested, and the luminance distribution of the OLED display panel 100 is collected by using the image acquisition device, such as testing the luminance and chromaticity coordinates of each pixel unit 21 by using an optical sensor. It should be noted that using this method to obtain the luminance of each pixel unit 21 requires testing a plurality of samples of the OLED display panel 100 to ensure accuracy and reliability of data. Meanwhile, due to the imperfection of the manufacturing process or the influence of the external environment, a normal display state of the OLED display panel 100 can be more accurately reflected by using this method to obtain the luminance distribution of the OLED display panel 100, so that the pixel opening area of the pixel unit 21 is more optimally adjusted to further optimize the display uniformity of the OLED display panel 100.

Furthermore, after using the above method to obtain corresponding luminance of each pixel unit 21, a preset luminance can be set when manufacturing the OLED display panel 100. In some embodiments, for the pixel unit 21 with a luminance less than the preset luminance, the pixel opening area thereof is correspondingly increased, and for the pixel unit 21 with a luminance greater than the preset luminance, the pixel opening area is correspondingly reduced, thereby maintaining the luminance of each pixel unit 21 same and optimizing the display uniformity of the OLED display panel.

In an embodiment of the present disclosure, referring to FIG. 8, a thin film transistor 41, an anode 42, and a pixel definition layer 43 can be successively disposed on the substrate 10. An opening 430 is defined on the pixel definition layer 43, and the pixel opening area of the pixel unit 21 is controlled by adjusting the opening 430 to form a pixel unit 21 with the corresponding pixel opening area, thereby optimizing the display uniformity of the OLED display panel 100.

The present disclosure provides the OLED display panel 100, the current distribution of the OLED display panel 100 is simulated through simulation software or luminance distributions of samples of the OLED display panel 100 are collected through an image acquisition device to obtain the luminance of each pixel unit 21, and the pixel opening area of the pixel unit 21 is correspondingly adjusted according to the luminance, so that the luminance of each pixel unit 21 remains consistent, thereby optimizing the display uniformity of the OLED display panel 100.

The above describes the embodiments of the present disclosure in detail. The article uses specific examples to explain the principles and implementation of the present disclosure. The descriptions of the above embodiments are merely used to help understand the method and core ideas of present disclosure; at the same time, for those of ordinary skill in the art, according to the ideas of the present disclosure, there will be changes in the specific implementation manner and application scope. In summary, the content of this specification should not be understood as a limitation of the present disclosure.

What is claimed is:

1. An organic light emitting diode (OLED) display panel, comprising:
a substrate comprising a display area; and
a plurality of pixel units arranged in an array in the display area; and
wherein each of the pixel units comprises a pixel opening area, and the pixel opening area is capable to be adjusted according to a luminance of a corresponding one of the pixel units, so as to ensure uniform display of the OLED display panel.

2. The OLED display panel in claim 1, wherein the OLED display panel further comprises a bonding area disposed outside the display area;
wherein the display area comprises a plurality of pixel areas arranged in a column, and each of the pixel areas comprises at least one row of the pixel units; and
wherein the pixel opening area of each of the pixel units in the pixel areas adjacent to the bonding area is less than the pixel opening area of each of the pixel units in the pixel areas away from the bonding area.

3. The OLED display panel in claim 2, wherein the pixel opening area of each of the pixel units in a same one of the pixel areas is same.

4. The OLED display panel in claim 2, wherein a plurality of fan-shaped wirings are disposed in the bonding area, and each of the fan-shaped wirings is connected to a corresponding one of the pixel units; and
wherein the plurality of fan-shaped wirings comprise first fan-shaped wirings and second fan-shaped wirings, a length of each of the first fan-shaped wirings is less than a length of each of the second fan-shaped wirings, and the pixel opening area of each of the pixel units connected to the first fan-shaped wirings is less than the pixel opening area of each of the pixel units connected to the second fan-shaped wirings.

5. The OLED display panel in claim 1, wherein the plurality of pixel units comprise at least one first pixel unit, the at least one first pixel unit is disposed in the display area irregularly, and a luminance of the first pixel unit is less than a preset luminance; and
wherein a pixel opening area of the first pixel unit is greater than a preset pixel opening area.

6. The OLED display panel in claim 1, wherein the plurality of pixel units comprise at least one second pixel unit, the at least one second pixel unit is disposed in the display area irregularly, and a luminance of the second pixel unit is greater than a preset luminance; and
wherein a pixel opening area of the second pixel unit is less than a preset pixel opening area.

7. The OLED display panel in claim 1, wherein each of the pixel units comprises a thin film transistor, an anode, and a pixel definition layer successively disposed on the substrate; and
wherein in any one of the pixel units, the pixel definition layer comprises an opening, and the pixel opening area of a corresponding one of the pixel units is capable to be adjusted according to a specification of the opening.

8. An organic light emitting diode (OLED) display panel, comprising:
a substrate comprising a display area; and
a plurality of pixel units arranged in an array in the display area; and
wherein each of the pixel units comprises a pixel opening area, and the pixel opening area is capable to be adjusted according to a luminance of a corresponding one of the pixel units, so as to ensure uniform display of the OLED display panel;
wherein the OLED display panel further comprises a bonding area disposed outside the display area;
wherein the display area comprises a plurality of pixel areas arranged in a column, and each of the pixel areas comprises at least one row of the pixel units;
wherein the pixel opening area of each of the pixel units in the pixel areas adjacent to the bonding area is less than the pixel opening area of each of the pixel units in the pixel areas away from the bonding area;
wherein each of the pixel units comprises a thin film transistor, an anode, and a pixel definition layer successively disposed on the substrate; and
wherein in any one of the pixel units, the pixel definition layer comprises an opening, and the pixel opening area of a corresponding one of the pixel units is capable to be adjusted according to a specification of the opening.

9. The OLED display panel in claim 8, wherein the pixel opening area of each of the pixel units in a same one of the pixel areas is same.

10. The OLED display panel in claim 8, wherein a plurality of fan-shaped wirings are disposed in the bonding area, and each of the fan-shaped wirings is connected to a corresponding one of the pixel units; and
wherein the plurality of fan-shaped wirings comprise first fan-shaped wirings and second fan-shaped wirings, a length of each of the first fan-shaped wirings is less than a length of each of the second fan-shaped wirings, and the pixel opening area of each of the pixel units connected to the first fan-shaped wirings is less than the pixel opening area of each of the pixel units connected to the second fan-shaped wirings.

11. The OLED display panel in claim 8, wherein the plurality of pixel units comprise at least one first pixel unit, the at least one first pixel unit is disposed in the display area irregularly, and a luminance of the first pixel unit is less than a preset luminance; and
wherein a pixel opening area of the first pixel unit is greater than a preset pixel opening area.

12. The OLED display panel in claim 8, wherein the plurality of pixel units comprise at least one second pixel unit, the at least one second pixel unit is disposed in the display area irregularly, and a luminance of the second pixel unit is greater than a preset luminance; and
wherein a pixel opening area of the second pixel unit is less than a preset pixel opening area.

13. A manufacturing method of an organic light emitting diode (OLED) display panel, comprising:
providing a substrate, wherein the substrate comprises a display area; and
forming a plurality of pixel units in the display area, each of the pixel units comprising a pixel opening area, and adjusting the pixel opening area according to a luminance of a corresponding one of the pixel units, so as to ensure uniform display of the OLED display panel.

14. The manufacturing method of the OLED display panel in claim 13, wherein a current distribution of the OLED display panel is simulated by simulation software, and the luminance of each of the pixel units is obtained according to the current distribution.

15. The manufacturing method of the OLED display panel in claim 13, wherein the OLED display panel is illuminated, and a luminance distribution of the OLED display panel is collected by an image acquisition device, so as to obtain the luminance of each of the pixel units.
